(19) United States
(12) Patent Application Publication
(10) Pub. No.: US 2005/0091622 A1
(43) Pub. Date: Apr. 28, 2005

(54) Method of grouping scan flops based on clock domains for scan testing

(76) Inventors: Krishna K. Pappu, San Jose, CA (US); Hunaid Hussain, Milpitas, CA (US); Arun Gunda, San Jose, CA (US)

Correspondence Address: Leo J. Peters;LSI Logic Corporation, MS D-106, 1551 McCarthy Blvd., Milpitas, CA, 95035, US

(21) Appl. No.: 10/695,853

(22) Filed: Oct. 28, 2003

(51) Int. Cl. G06F 9/45; G01R 31/28

(52) U.S. Cl. 716/6; 714/726

(57) ABSTRACT

A method of grouping cells in an integrated circuit design includes steps of: (a) receiving as input a representation of an integrated circuit design; (b) initializing a corresponding list of cells for a common signal domain in the integrated circuit design; (c) selecting a cell belonging to a common signal domain that is not included in a corresponding list of cells for a common signal domain; (d) tracing a net from an input port of the selected cell to a signal driver and inserting the selected cell in the corresponding list of cells for the common signal domain associated with the signal driver; and (e) tracing the net to an input port of each cell connected to the signal driver and inserting each cell traced from the net in the corresponding list of cells for the common signal domain associated with the signal driver.

### BACKGROUND OF THE INVENTION

1. Field of the Invention

The present invention is directed to the testing of integrated circuit devices. More specifically, but without limitation thereto, the present invention is directed to a method of testing integrated circuits that contain synchronously clocked elements.

2. Description of Related Art

Modern electronics systems have increased dramatically in circuit density. For example, the densities of integrated circuits have increased from a few hundred transistors per chip in the 1960's to several million transistors per chip in integrated circuits manufactured today. Integrated circuit packaging density has increased from the previous relatively low density dual in-line package (DIP) having a typical pin count of 8 to 40 pins and a pin spacing of 0.1 inch to the current fine-pitch technology (FPT), tape-automated bonding (TAB), and multi-chip modules (MCMs) that provide hundreds of pins in relatively small packages. Conductive trace spacing and trace width on printed circuit boards has also decreased, so that a large number of signals may be routed in a small space. Multi-layer printed circuit boards and single and double-sided surface mount techniques are combined with high levels of integration and high-density integrated circuit packaging techniques to provide extremely dense electronic systems.

As the density of electronic devices increases, device testing becomes increasingly difficult. Traditional test methods include testing circuit board assemblies with testers having a large number of spring-loaded contact pins that make contact with test points on a printed circuit board. Modern fine-pitch technology packages, multi-layer printed circuit boards, and double-sided surface mount techniques frustrate attempts to test high density electronic systems with traditional test methods.

Application specific integrated circuits (ASICs) routinely achieve densities of up to 100,000 gates per chip, which presents an especially difficult testing challenge. ASICs are typically designed by combining pre-defined, standard functional blocks called core cells from a variety of sources with discrete logic to perform a desired function or group of functions. Although standard test vectors or test strategies may be supplied with the core cells, their internal connections to one another inside the ASIC are frequently inaccessible from the pins of the ASIC, rendering the standard tests unusable and complicating the testing procedure.

A common technique used to gain access to core cells inside an ASIC is known as MUX isolation. In MUX isolation, a test mode or test signal is provided that changes the function of certain pins of the ASIC in the test mode. Multiplexers are used in the test mode to connect the ordinarily inaccessible signals of the core cells to the pins of the ASIC that are not needed during the test mode. When the test signal or test mode is removed, the ASIC pins revert to their normal function. The MUX isolation technique is not always practical or possible, for example, when there are more signals at the periphery of a core cell than there are pins on the ASIC that contains the core cell.

Another technique used for testing ASICs is full-scan design, in which every flip-flop, or flop, of a logic circuit has a multiplexer placed at its data input, so that when a test mode signal is applied to the control input of the multiplexers, all the flip-flops are chained together into a shift register. The shift register is then used to clock in test patterns (stimuli) and to clock out the test results (responses).

### SUMMARY OF THE INVENTION

In one aspect of the present invention, a method of grouping scan flops for scan testing comprising steps of:
(a) receiving as input a representation of an integrated circuit design;
(b) initializing a corresponding list of cells for a common signal domain in the integrated circuit design;
(c) selecting a cell belonging to a common signal domain that is not included in a corresponding list of cells for a common signal domain;
(d) tracing a net from an input port of the selected cell to a signal driver and inserting the selected cell in the corresponding list of cells for the common signal domain associated with the signal driver; and
(e) tracing the net to an input port of each cell connected to the signal driver and inserting each cell traced from the net in the corresponding list of cells for the common signal domain associated with the signal driver.

In another aspect of the present invention, a computer program product for grouping scan flops for scan testing includes a medium for embodying a computer program for input to a computer and a computer program embodied in the medium for causing the computer to perform steps of:
(a) receiving as input a representation of an integrated circuit design;
(b) initializing a corresponding list of cells for a common signal domain in the integrated circuit design;
(c) selecting a cell belonging to a common signal domain that is not included in a corresponding list of cells for a common signal domain;
(d) tracing a net from an input port of the selected cell to a signal driver and inserting the selected cell in the corresponding list of cells for the common signal domain associated with the signal driver; and
(e) tracing the net to an input port of each cell connected to the signal driver and inserting each cell traced from the net in the corresponding list of cells for the common signal domain associated with the signal driver.

### BRIEF DESCRIPTION OF THE DRAWINGS

The present invention is illustrated by way of example and not limitation in the accompanying figures, in which like references indicate similar elements throughout the several views of the drawings, and in which:

FIG. 1 illustrates a typical scan chain for an integrated circuit design of the prior art;

FIG. 2 illustrates a flow chart for a method of grouping flip-flops in a scan chain according to the prior art; and

FIG. 3 illustrates a flow chart for a method of grouping flip-flops in a scan chain according to an embodiment of the present invention.

Elements in the figures are illustrated for simplicity and clarity and have not necessarily been drawn to scale. For example, the dimensions of some elements in the figures may be exaggerated relative to other elements to point out distinctive features in the illustrated embodiments of the present invention.

### DESCRIPTION OF THE ILLUSTRATED EMBODIMENTS

In the process of generating a full-scan design of an integrated circuit, a tool is used to search through the scan chains and to group flip-flops that are driven by the same clock, that is, flip-flops that share a common clock domain. Because flip-flops are only reordered within their respective clock domains, the information produced by the search is important for disconnecting and subsequently reordering the flip-flops in a scan chain. If flip-flops from different clock domains are stitched together, then timing violations are likely to result causing test failures and functional failures. After disconnecting the scan chains, the placement tool can place scan flip-flops anywhere on the integrated circuit die, because the scan chain is not on the critical timing path. After the placement is done, the scan chain is restitched based on the placement information of each of the flip-flops within their respective clock domains.

A typical tool previously used to search through the scan chains traces the data input port of the first scan flip-flop in a scan chain to the output port of the last scan flip-flop in the scan chain. After all the flip-flops in a scan chain have been identified, the tool traces the clock input of each flip-flop to the clock driver. The clock driver may be, for example, an I/O port at the top level of the integrated circuit design. A scan chain typically has 5,000 to 10,000 scan flip-flops in an integrated circuit design, which results in an equal number of traces to find the clock driver. Also, a typical design includes between 16 and 32 scan chains. As a result, a costly period of testing time is required to complete a trace and grouping of all the scan chains in an integrated circuit design.

A multi-threading approach used to reduce the testing time allocates a separate thread to trace each clock path, however, an adequate number of CPU's is required to allocate resources to each thread. Another problem is that the total trace time still depends on the time required to trace the largest scan chain. For example, if four scan chains each having an equal length of 10,000 flip-flops requires 20 hours to trace, then five hours would be required in an ideal multi-threading allocation of resources to four threads in a parallel processing environment. Another disadvantage of the multi-threading approach is the complexity of designing an algorithm to manage threads and to merge the results from each of the threads.

Alternatively, the scan chains may be traced manually to specify the scan clock domains. This approach has the disadvantages of being prone to human error, and becomes impractical for extremely large integrated circuit designs.

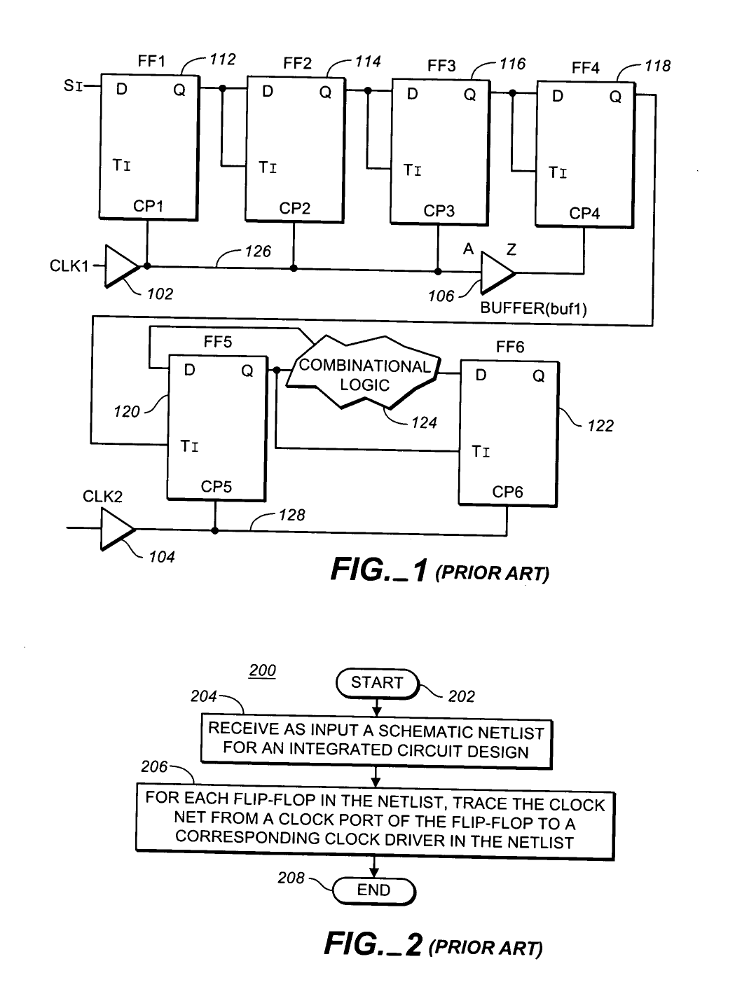

FIG. 1 illustrates a typical scan chain 100 for an integrated circuit design of the prior art. Shown in FIG. 1 are clock drivers 102 and 104, a clock buffer 106, flip-flops 112, 114, 116, 118, 120 and 122, a logic cloud 124, and clock nets 126 and 128.

The clock driver 102 distributes a first clock signal CLK1 to the clock inputs of flip-flops 112, 114, 116 and 118 on the clock net 126. The clock driver 104 distributes a second clock signal CLK2 to the clock inputs of flip-flops 120 and 122 on the clock net 128.

FIG. 2 illustrates a flow chart 200 for a method of grouping flip-flops in a scan chain according to the prior art.

Step 202 is the entry point of the flow chart 200.

In step 204, a representation of an integrated circuit design, for example, a netlist, is received as input.

In step 206, for each flip-flop in the netlist, a clock net is traced from a clock port of the flip-flop to a corresponding clock driver in the netlist.

Step 208 is the exit point of the flow chart 200.

The simplicity of the method illustrated by the flow chart 200 is unfortunately outweighed by the lengthy time required to trace the clock input port of each flip-flop to the corresponding clock driver in the netlist.

The present invention exploits the fact that most of the flip-flops in a scan chain share a common clock domain. In this example, the six flip-flops in the scan chain 100 share the two clock domains connected to the clock signals CLK1 and CLK2 by the clock nets 126 and 128 respectively.

In one aspect of the present invention, a method of grouping scan flops for scan testing includes steps of:
(a) receiving as input a representation of an integrated circuit design;
(b) initializing a corresponding list of cells for a common signal domain in the integrated circuit design;
(c) selecting a cell belonging to a common signal domain that is not included in a corresponding list of cells for a common signal domain;
(d) tracing a net from an input port of the selected cell to a signal driver and inserting the selected cell in the corresponding list of cells for the common signal domain associated with the signal driver; and
(e) tracing the net to an input port of each cell connected to the signal driver and inserting each cell traced from the net in the corresponding list of cells for the common signal domain associated with the signal driver.

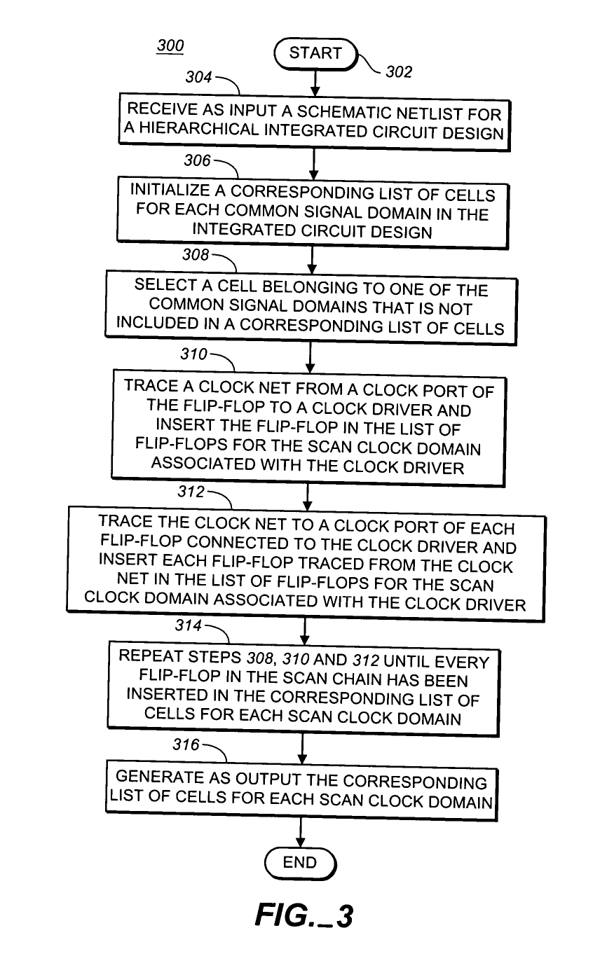

FIG. 3 illustrates a flow chart 300 for a method of grouping flip-flops in a scan chain according to an embodiment of the present invention.

Step 302 is the entry point of the flow chart 300.

In step 304, a representation of an integrated circuit design, such as a netlist, is received as input. In this example, the netlist includes a scan chain used to test the integrated circuit design.

In step 306, a corresponding list of cells for each common signal domain in the integrated circuit design is initialized, that is, created as an empty list. In one embodiment of the present invention, the cells are flip-flops, and a corresponding list of flip-flops is created for each scan clock domain in the integrated circuit design.

In step 308, a cell belonging to one of the common signal domains that is not included in a corresponding list of cells is selected. For example, each list of flip-flops may be compared with a selected flip-flop to determine whether the selected flip-flop is included in any of the lists. If so, then the comparison may be repeated for the next flip-flop, and so on, until a selected flip-flop is not found in any of the lists.

In step 310, a clock net is traced from a clock port of the flip-flop to a clock driver, and the flip-flop is inserted in the list of flip-flops for the scan clock domain associated with the clock driver. In the example of FIG. 1, the clock port CP1 of the flip-flop 112 is traced to the clock driver 102, and the name of the flip-flop 112 is inserted in the list of flip-flops for the scan clock domain associated with the clock driver 102.

In step 312, the clock net is traced to a clock port of each flip-flop connected to the clock driver, and each flip-flop traced from the clock net is inserted in the list of flip-flops for the scan clock domain associated with the clock driver. In the example of the clock net 126, the clock net is traced to the clock ports CP1, CP2 and CP3 of the flip-flops 112, 114 and 116 respectively and through the clock buffer 106 to the clock port CP4 of the flip-flop 118. For the clock domain CLK2, the clock net 128 is traced to the clock ports CP5 and CP6 of the flip-flops 120 and 122.

The name of each flip-flop traced from the clock net is stored in the list of flip-flops for the corresponding scan clock domain. In the example of FIG. 1, the netlist names of flip-flops 112, 114, 116 and 118 are stored in the list of flip-flops for the clock domain CLK1, and the netlist names of flip-flops 120 and 122 are stored in the list of flip-flops for the clock domain CLK2.

In step 314, steps (c), (d) and (e) are repeated until every flip-flop in the scan chain has been inserted in the corresponding list of cells for each scan clock domain.

In step 316, the corresponding list of cells for each scan clock domain is generated as output.

Step 318 is the exit point of the flow chart 300.

The steps described above with regard to the flow chart 300 may also be implemented by instructions performed on a computer according to well-known programming techniques.

In an alternative embodiment, the method described above for grouping flip-flops for scan testing may be used to group any type of cells in an integrated circuit design that are connected to a common signal. For example, all the multiplexers that are connected to a common control signal may be grouped in a list for that control signal domain, and so on.

In another aspect of the present invention, a computer program product for grouping scan flops for scan testing includes a medium for embodying a computer program for input to a computer and a computer program embodied in the medium for causing the computer to perform steps of:
(a) receiving as input a representation of an integrated circuit design;
(b) initializing a corresponding list of cells for a common signal domain in the integrated circuit design;
(c) selecting a cell belonging to a common signal domain that is not included in a corresponding list of cells for a common signal domain;
(d) tracing a net from an input port of the selected cell to a signal driver and inserting the selected cell in the corresponding list of cells for the common signal domain associated with the signal driver; and
(e) tracing the net to an input port of each cell connected to the signal driver and inserting each cell traced from the net in the corresponding list of cells for the common signal domain associated with the signal driver.

Although the method of the present invention illustrated by the flowchart descriptions above are described and shown with reference to specific steps performed in a specific order, these steps may be combined, sub-divided, or reordered without departing from the scope of the claims. Unless specifically indicated herein, the order and grouping of steps is not a limitation of the present invention.

While the invention herein disclosed has been described by means of specific embodiments and applications thereof, numerous modifications and variations could be made thereto by those skilled in the art without departing from the scope of the invention set forth in the following claims.

1. A method of grouping cells in an integrated circuit design comprising steps of:
(a) receiving as input a representation of an integrated circuit design;
(b) initializing a corresponding list of cells for a common signal domain in the integrated circuit design;
(c) selecting a cell belonging to a common signal domain that is not included in a corresponding list of cells for a common signal domain;
(d) tracing a net from an input port of the selected cell to a signal driver and inserting the selected cell in the corresponding list of cells for the common signal domain associated with the signal driver; and
(e) tracing the net to an input port of each cell connected to the signal driver and inserting each cell traced from the net in the corresponding list of cells for the common signal domain associated with the signal driver.

2. The method of claim 1 further comprising a step (f) of repeating steps (c), (d) and (e) until every cell belonging a common signal domain has been inserted in a corresponding list of cells for the common signal domain.

3. The method of claim 2 further comprising a step (g) of generating as output a corresponding list of cells for a common signal domain in the integrated circuit design.

4. The method of claim 1 wherein step (d) includes storing a name of the selected cell in the corresponding list of cells for the common signal domain associated with the signal driver.

5. The method of claim 1 comprising performing steps (b), (c), (d) and (e) for cells that are flip-flops in a scan chain.

6. The method of claim 5 comprising performing steps (b), (c), (d) and (e) for a common signal domain that is a scan clock domain.

7. The method of claim 6 comprising performing steps (d) and (e) for a net that is a clock net.

8. The method of claim 7 comprising performing steps (d) and (e) for an input port that is a clock port.

9. The method of claim 8 comprising performing steps (d) and (e) for a signal driver that is a clock driver.

10. A computer program product for grouping scan flops for scan testing comprising:
a medium for embodying a computer program for input to a computer; and
a computer program embodied in the medium for causing the computer to perform steps of:
(a) receiving as input a representation of an integrated circuit design;
(b) initializing a corresponding list of cells for a common signal domain in the integrated circuit design;
(c) selecting a cell belonging to a common signal domain that is not included in a corresponding list of cells for a common signal domain;
(d) tracing a net from an input port of the selected cell to a signal driver and inserting the selected cell in the corresponding list of cells for the common signal domain associated with the signal driver; and
(e) tracing the net to an input port of each cell connected to the signal driver and inserting each cell traced from the net in the corresponding list of cells for the common signal domain associated with the signal driver.

11. The computer program product of claim 10 further comprising a step (f) of repeating steps (c), (d) and (e) until every cell belonging a common signal domain has been inserted in a corresponding list of cells for the common signal domain.

12. The computer program product of claim 11 further comprising a step (g) of generating as output a corresponding list of cells for a common signal domain in the integrated circuit design.

13. The computer program product of claim 10 wherein step (d) includes storing a name of the selected cell in the corresponding list of cells for the common signal domain associated with the signal driver.

14. The computer program product of claim 10 comprising performing steps (b), (c), (d) and (e) for cells that are flip-flops in a scan chain.

15. The computer program product of claim 14 comprising performing steps (b), (c), (d) and (e) for a common signal domain that is a scan clock domain.

16. The computer program product of claim 15 comprising performing steps (d) and (e) for a net that is a clock net.

17. The computer program product of claim 16 comprising performing steps (d) and (e) for an input port that is a clock port.

18. The computer program product of claim 17 comprising performing steps (d) and (e) for a signal driver that is a clock driver.
